(19) United States
(12) Patent Application Publication
(10) Pub. No.: US 2010/0158338 A1
(43) Pub. Date: Jun. 24, 2010

(54) METHOD AND APPARATUS FOR ACQUISITION OF A MAGNETIC RESONANCE IMAGE

(76) Inventors: Martin Harder, Nuernberg (DE); Jan Ruff, Muenchen (DE)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/641,547

(22) Filed: Dec. 18, 2009

(30) Foreign Application Priority Data
Dec. 19, 2008 (DE) 10 2008 064 106.5

(51) Int. Cl. G06K 9/62; G01R 33/48

(52) U.S. Cl. 382/131; 324/309

(57) ABSTRACT

In a method for image data acquisition with a magnetic resonance device that has a movable patient table, a localizer of the anatomy of a patient is acquired, suitable slice geometry information is automatically determined from the localizer for the diagnostic question, a patient table position is automatically determined under consideration of the slice geometry information, that causes a slice or slice group determined from the slice geometry information to be in or optimally close to the isocenter of the magnetic resonance device, the patient table is automatically driven into the patient table position, and the diagnostic image data are acquired.

### BACKGROUND OF THE INVENTION

1. Field of the Invention

The present invention concerns a method for image acquisition with a magnetic resonance apparatus that has a movable patient table, and an associated magnetic resonance apparatus.

2. Description of the Prior Art

In an examination with a magnetic resonance apparatus, specific slices of a patient are acquired that form at least a part of the region of interest of the patient. The correct setting of these slices with regard to the slice geometry, i.e. the position, orientation and thickness of the slice, can be conducted by experienced users through a user interface at the magnetic resonance device. This procedure is complicated and extremely difficult.

Therefore, methods have been proposed in which suitable slice geometry information for the diagnostic question can automatically be obtained from preliminary scans known as localizers (frequently also called scout exposures). As an example, U.S. Pat. No. 6,195,409 discloses initially analyzing a localizer in order to learn structural information about the patient from which optimal diagnostic scan parameters (in particular shoe geometry information) can be derived.

It is not unusual for a slice position that lies outside of the isocenter of the magnetic resonance apparatus to be designated by such slice geometry information determined by automatic localizer analyses. This leads to a reduction in the diagnostic image quality, and particularly severe limitations arise in the use of a magnetic apparatus that has a short magnet. It is possible to conduct a rough manual positioning of the patient table, such that the region of interest is located at least roughly in the isocenter, but this method is error-prone and complicated.

### SUMMARY OF THE INVENTION

An object of the present invention is to provide a method for designating slice geometry for a magnetic resonance diagnostic image with which the effort for an operator is reduced and the image quality is markedly increased, wherein in particular a reproducibility of image data acquisitions should be enabled.

This object is achieved in accordance with the invention by a method wherein a localizer of the anatomy of a patient is acquired, suitable slice geometry information is automatically determined from the localizer for the diagnostic question, a patient table position is automatically determined under consideration of the slice geometry information, that cause a slice or slice group determined from the slice geometry information to be in or optimally close (substantially adjacent) to the isocenter of the magnetic resonance device, and the patient table is automatically driven into the determined patient table position and the diagnostic image data are acquired.

Through the acquisition of the localizer it is known not only which slice geometry is ideal, but also the position of the isocenter is known. Since the patient table is movable, a patient table position can consequently be determined in which the slice (or slice group) to be acquired lies in the isocenter or is at least optimally close to the isocenter. By a corresponding control of the patient table, this position is additionally automatically taken up so that an image data acquisition can ensue with excellent quality. In the method according to the invention, three-dimensional or four-dimensional localizers (wherein the fourth dimension is time) are normally used that are acquired by means of a two-dimensional or three-dimensional imaging technique.

The image quality is thus increased not because slice geometry information is determined that reflects the ideal acquisition geometry but also it is insured that the measurement optimally always occurs in the isocenter, which results in an increase quality of the acquired image data. The method requires no further interventions by the user whatsoever, and it is not subject to possible errors or inaccuracies in a rough patient positioning by a user. Furthermore, a high level of reproducibility of the data advantageously results, since the data are acquired not only in the same slice geometry but also always at an optimally ideal position in the field of the magnet of the magnetic resonance device. A manual rough positioning is avoided, and regions of interest that are difficult to externally localize (for example organs such as the prostate) can be positioned better and with more certainty. The measurement can be shortened by a localizer that checks the initial manual patient positioning.

In this way it is possible with the method according to the invention both to increase the usage comfort and the image quality and to generate reproducible framework conditions for image data acquisitions.

In an embodiment of the present invention, a distance between the middle point of the slice or slice group defined by the slice geometry information and the isocenter is minimized under consideration of the movement possibilities of the patient table to determine the patient table position. For example, if the patient table can be displaced only in the z-direction by means of a solenoid magnet (thus along the longitudinal axis of the magnet), a table position can be chosen at which the middle point is located at the same height as the isocenter in the z-direction. If additional adjustment possibilities are provided, the distance can naturally also be additionally shortened. In particular, the slice or slices can be designated based on that the center point and the isocenter at the determined table position coinciding given an arbitrarily movable patient table, thus a patient table that can in particular be moved in all three spatial directions.

It is not unusual for different coordinate systems to be used in the context of the invention, namely a gradient coordinate system (GCS), whose origin is the isocenter of the magnetic resonance device, and a patient coordinate system (PCS), whose origin is the point in the patient that is in the isocenter of the magnetic resonance device in the first data acquisition. The slice geometry information is now determined in this patient coordinate system, for example. However, since the patient coordinate system is merely displaced by table movements relative to the gradient coordinate system, it is known at any time how the two coordinate systems can be transformed into one another, and in particular what effect the table position has on where slices or slice groups defined by the slice geometry information are located relative to the isocenter. The ideal patient table position can also be easily determined and translated into corresponding control parameters for the patient table. For some diagnostic questions, the region of interest—and thus also the slice group described by the slice geometry information may be larger in terms of its extent than a homogeneity region extending around the isocenter. It can then be provided according to the invention that the image data acquisition is divided into multiple partial image data acquisitions, meaning that multiple partial slice groups are defined that are acquired in one acquisition step. In the method according to the invention, multiple patient table positions that are determined are occupied during the image data acquisition. This means that a patient table position in which the partial slice group lies optimally close to the isocenter is determined for every partial slice group. When the acquisitions of this partial slice group are concluded, a new patient table position is occupied and the partial slice group associated with this patient table position is acquired. Such a procedure can be advantageously applied in spinal column examinations, for example. Even for acquisitions that ensue in multiple steps can ensue in multiple steps, such a procedure can be reasonable when, for example, the head of a patient should initially be acquired in order to subsequently acquire the spinal column at least in part.

In another advantageous embodiment of the present invention, additional image acquisition parameters are determined depending on the slice geometry information and/or the patient table position; in particular, local coils are selected for image data acquisition. For example, it is known at which position local coils (for example head coil, neck coil, back coil and the like) are located on the patient table. The patient table position that was determined indicates where the patient table is located in comparison to the isocenter and the slices to be acquired so that it is advantageously possible to automatically select the local coils at which the best image quality is to be expected with regard to the current geometry.

The invention also encompasses a magnetic resonance apparatus with a movable patient table and a control system configured to execute the method according to the invention. All statements above with regard to the method are applicable to the magnetic resonance system. In particular, the control system is configured not only to automatically determine suitable slice geometry information for the diagnostic question from the localizer, but also to determine a patient table position under consideration of the slice geometry information to cause a slice or slice group determined by the slice geometry information to be in or optimally close (substantially adjacent) to the isocenter of the magnetic resonance device. Furthermore, the control apparatus can control the patient table accordingly in order to move it into the patient table position.

A completely automated image data acquisition at high quality thus can ensue with the method according to the invention and the magnetic resonance system according to the invention.

### BRIEF DESCRIPTION OF THE DRAWINGS

FIG. 1 is a flowchart of the method according to the invention.

FIG. 2 schematically illustrates geometry factors that are relevant to the inventive method.

FIG. 3 illustrates a magnetic resonance apparatus according to the invention.

### DESCRIPTION OF THE PREFERRED EMBODIMENTS

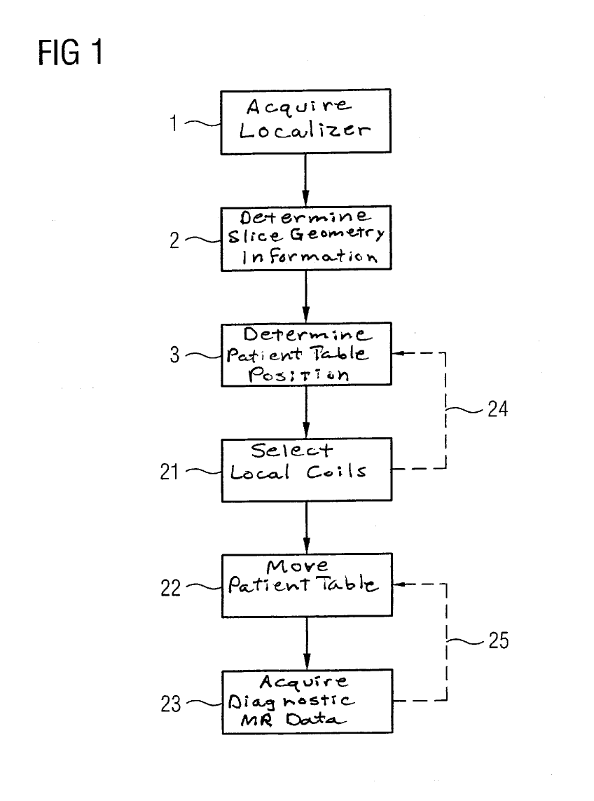

FIG. 1 shows a workflow of the method according to the invention. A localizer that, as an overview exposure, shows the anatomy of a patient is acquired first in Step 1. Slice geometry information suitable for the diagnostic question are now automatically determined from the localizer in Step 2 in a manner that is basically known. These procedures are known in principle and do not require any more detailed presentation here.

The slice geometry information can thereby be determined in a patient coordinate system, for example, which patient coordinate system is defined by the position of the isocenter in the first executed acquisition as an origin. The transformation between the patient coordinate system and the gradient coordinate system (which is stationary and always exhibits the isocenter as an origin point) is thus known in principle due to the ability to track the table movements.

It is therefore also possible in principle to derive the relevant position of the slices to be acquired and of the isocenter of the magnetic resonance device so that in Step 3 of the method according to the invention a patient table position that is ideal for the acquisition can be determined. This is by the slice or slice group determined by the slice geometry information being in or optimally close to the isocenter of the magnetic resonance device.

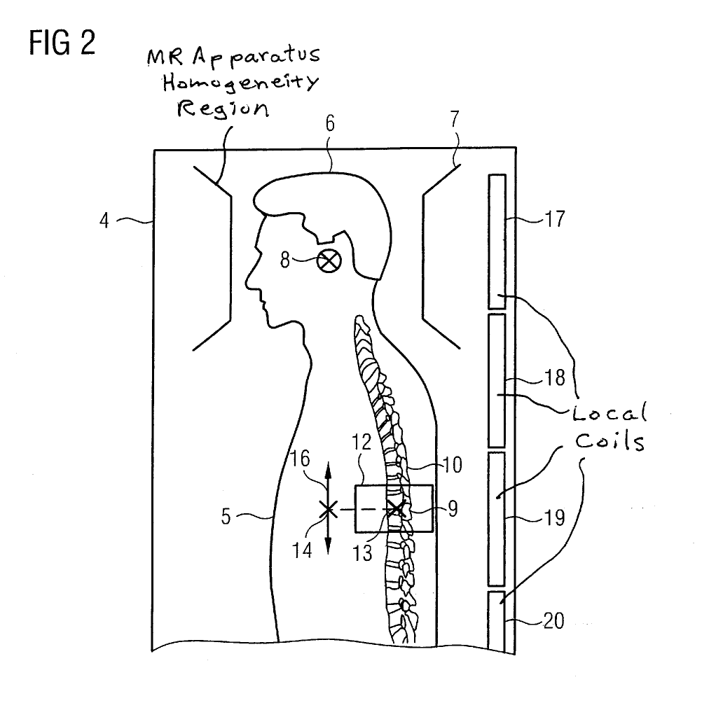

More specifically, the middle point of the determined slice or slice group is caused to be optimally close to the isocenter, which also represents a point, meaning that the distance between the two is minimized and the associated patient table position is sought. This is shown as an example in FIG. 2. A patient 5 supported on a patient table 4 is shown in FIG. 2. In the shown example, it is assumed that an acquisition of the head 6 (i.e. acquisition of MR data representing the head 6) of the patient 5 has initially erisued. The homogeneity region of the magnetic resonance device (clearly indicated by the brackets 7) which extends around the isocenter 8, is accordingly located at the level of the head 6. The following procedure (as an exampled) is for acquiring a specific vertebra 9 of the spinal column 10 of the patient, for which slice geometry information that describes a slice 12 with a middle point 13 has already been determined from the localizer in Step 2. As can be seen, the slice 12 is located at a significant distance from the isocenter 8 so that, if steps were not taken in accordance with the invention, an image acquisition would be of qualitatively poor quality. Therefore, according to the invention, the current position 14 of the patient table 4 is not used, but instead is used a new patient table position is automatically determined in which the isocenter 8 lies optimally close to the center point 13 of the slice 12. Presently the patient table position 14 is marked at the level of the center point 13 for the purpose of a simpler representation. In general, however, this can be arbitrarily defined. Presently an example is shown in which the patient table 4 can be moved only along the z-direction, such that the isocenter 8 and the center point 13 lie at the same level in the z-direction here due to the definition of the patient table position 14. The patient table 4 is thus displaced along the axis 16 so that the points 14 and 8 are substantially coincident. Naturally, given additional degrees of freedom it is conceivable to bring the middle point 13 and the isocenter 8 even closer to one another. In particular, a new patient table position can be determined so that the middle point 13 and the isocenter 8 coincide when the patient table 4 can be moved in all three spatial directions.

In Step 21, the local coils 17, 18, 19, 20 (likewise indicated in FIG. 2) with which the image acquisition should ensue are now selected as additional image acquisition parameters. When the patient table 4 is located in the new patient table position (which here corresponds to the isocenter 8), the local coil 19 is clearly (see FIG. 2) located in a suitable image acquisition position in the shown example. This is then used later in the image acquisition.

The determined patient table position is then automatically taken up by the patient table in Step 22, whereupon the acquisition of the diagnostic image data can ensue in Step 23.

The inventive method is particularly useful when the region of interest, or the slice group described by the slice geometry information, have very large dimensions, for example when the diagnostic question requires an acquisition of the entire spinal column. In order to generate exposures of high quality it is then reasonable to divide the slice group into multiple partial slice groups, for each of which a patient table position is then respectively determined according to Steps 3, 21, as indicated by the arrow 24.

In the further course of the workflow, the corresponding patient table positions are then occupied and the respective partial slice groups are acquired (see arrow 25).

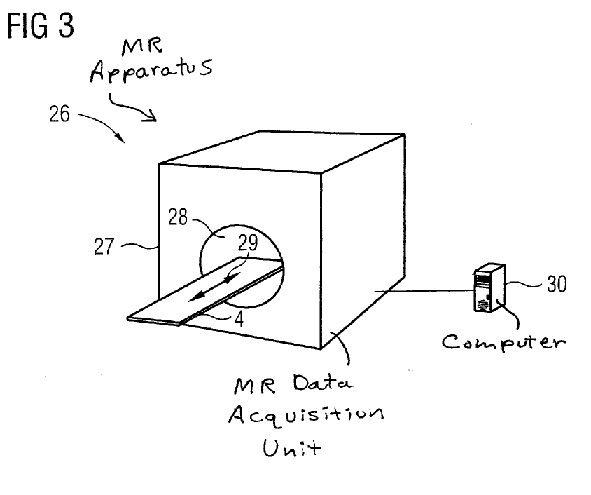

FIG. 3 shows a magnetic resonance apparatus 26 according to the invention. It has a magnetic resonance data acquisition unit (scanner) 27 with a patient receptacle 28 into which the patient table 4 can be driven. The patient table 4 is therefore movable at least along the longitudinal direction of the image acquisition and the acquisition unit 27, thus the z-direction, as is indicated by arrow 29.

The magnetic resonance apparatus 26 also has a control computer (or distributed computer system) 30 that controls all components of the magnetic resonance apparatus 26 (thus also the patient table 4). This control computer 30 is configured to implement the Steps 2, 3, 21 and 22 shown above and to produce the corresponding control for Steps 1 and 23. In this way the method according to the invention runs completely automatically in the magnetic resonance apparatus 26.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for acquiring magnetic resonance data with a magnetic resonance apparatus that comprises a moveable patient table, said method comprising the steps of:
operating a magnetic resonance data acquisition unit, with a patient located therein on a movable patient table, to obtain a localizer image representing anatomy of the patient;
supplying said localizer image to a processor and, in said processor, automatically determining slice geometry information from the localizer image that is relevant to a diagnostic question for which a subsequent diagnostic image is to be obtained;
in said processor, automatically determining a patient table position for said patient table from said slice geometry information that causes a slice or slice group determined from the slice geometry information to be in or substantially adjacent to an isocenter of the magnetic resonance data acquisition unit;
from said processor, controlling movement of the patient table to automatically move the patient table to said patient table position; and
operating the magnetic resonance data acquisition unit to acquire diagnostic image data from the patient on the patient table in said patient table position, for said diagnostic image.

2. A method as claimed in claim 1 comprising, in said processor, determining said patient table position by minimizing a distance between the isocenter and a middle point of the slice or slice group defined by the slice geometry information, dependent on movement capability of said patient table.

3. A method as claimed in claim 1 wherein said magnetic resonance data acquisition unit comprises a homogeneity region that extends around said isocenter and comprising, in said processor, determining a slice group from said slice geometry information and dividing said slice group into a plurality of sub-groups and, for each sub-group, determining a patient table position of said patient table that causes the respective sub-group to be in or substantially adjacent to the isocenter, and controlling movement of said patient table to successively cause said patient table to occupy each of the respective patient table positions, and to acquire magnetic resonance data for the respective sub-groups only when the patient table is in the patient table position determined for that sub-group.

4. A method as claimed in claim 1 comprising, in said processor, automatically determining additional image acquisition parameters for use in acquiring said diagnostic image dependent on at least one of said slice geometry information and said patient table position.

5. A method as claimed in claim 4 comprising determining, as at least one of said additional image acquisition parameters, a position of a local coil in said magnetic resonance data acquisition unit for acquiring said diagnostic magnetic resonance image data representing said diagnostic image.

6. A magnetic resonance apparatus comprising:
a magnetic resonance data acquisition unit that is operable to acquire magnetic resonance data;
a patient table that is adapted to receive a patient thereon and that is moveable relative to said data acquisition unit;
a computerized control system that operates said magnetic resonance data acquisition unit, with a patient located therein on the patient table, to obtain a localizer image representing anatomy of the patient;
said computerized control system comprising a processor supplied with said localizer image, said processor being configured to automatically determine slice geometry information from the localizer image that is relevant to a diagnostic question for which a subsequent diagnostic image is to be obtained;
said processor being configured to automatically determine a patient table position for said patient table from said slice geometry information that causes a slice or slice group determined from the slice geometry information to be in or substantially adjacent to an isocenter of the magnetic resonance data acquisition unit;
said control unit being configured to control movement of the patient table to automatically move the patient table to said patient table position; and
said control unit being configured to operate the magnetic resonance data acquisition unit to acquire diagnostic image data from the patient on the patient table in said patient table position, for said diagnostic image.
